(19) United States
(12) Patent Application Publication
(10) Pub. No.: US 2026/0269195 A1
(43) Pub. Date: Sep. 10, 2026

(54) TUNABLE EDGE SHEATH WITH NANOSECOND RF PULSES

(71) Applicant: Lam Research Corporation, Fremont, CA (US)

(72) Inventors: Alexei MARAKHTANOV, Albany, CA (US); Felix Leib KOZAKEVICH, Sunnyvale, CA (US); Kenneth LUCCHESI, Newark, CA (US); Bing JI, Pleasanton, CA (US); John HOLLAND, San Jose, CA (US); Bongseong KIM, San Ramon, CA (US)

(21) Appl. No.: 19/480,011

(22) PCT Filed: May 1, 2024
(86) PCT No.: PCT/US2024/027311

§ 371 Date: Oct. 29, 2025

Related U.S. Application Data
(60) Provisional application No. 63/500,545, filed on May 5, 2023.

(51) Int. Cl. H01J 37/32; H10P 72/00; H10P 72/72

(52) U.S. Cl. CPC H01J 37/32706; H01J 37/32091; H01J 37/32568; H01J 37/32715; H10P 72/0421; H10P 72/722; H01J 2237/2007; H01J 2237/24564; H01J 2237/3341

(57) ABSTRACT

A system including a plasma chamber configured for generating plasma, wherein the plasma chamber includes a lower electrode located within an electrostatic chuck. The system including an upper electrode disposed above the lower electrode, and an edge ring surrounding the lower electrode. The system including a first nanosecond direct current (DC) pulsing generator electrically coupled to the lower electrode, and configured for supplying a first low frequency pulsed DC power signal to the lower electrode, wherein the first low frequency pulsed DC power signal is non-sinusoidal. The system including a second nanosecond DC pulsing generator electrically coupled to the edge ring, and configured for supplying a second low frequency pulsed DC power signal to the edge ring, wherein the second low frequency pulsed DC power signal is non-sinusoidal, and is substantially aligned with a frequency and phase and pulse shape of the first low frequency pulsed DC power signal.

### TECHNICAL FIELD

The present embodiments relate to plasma generation, and more specifically to systems and methods for implementing a tunable edge sheath using nanosecond direct current pulses without corresponding matching networks and that are substantially aligned.

### BACKGROUND OF THE DISCLOSURE

Many modern semiconductor chip fabrication processes such as plasma etching processes are performed within a plasma processing chamber in which a substrate, e.g., wafer, is supported on an electrostatic chuck (ESC). In plasma etching processes, the wafer is exposed to a plasma generated within a plasma processing volume. Plasma contains various types of radicals, electrons, as well as positive and negative ions. The chemical reactions of the various radicals, electrons, positive ions, and negative ions are used to etch features, surfaces and materials of a wafer.

For example, when a process gas is supplied into the plasma processing chamber, a radio frequency (RF) signal provides power and is applied to at least one of the electrodes of the plasma processing chamber to form an electric field between the electrodes. The process gas is turned into plasma by the RF signal, thereby performing plasma etching on a predetermined layer disposed on the wafer. Unfortunately, during wafer processing, the plasma may result in an ion angular spread (e.g., ion tilt angles) occurring along the extreme edge of the wafer which may cause non-uniformity of features along the extreme edge of the wafer.

It is in this context that embodiments of the disclosure arise.

### SUMMARY

The present embodiments relate to systems and methods for implementing a tunable edge sheath using nanosecond direct current (DC) pulses without corresponding matching networks and that are substantially aligned. Several inventive embodiments of the present disclosure are described below.

Embodiments of the present disclosure provide for a system for generating plasma. The system including a plasma chamber configured for generating plasma, wherein the plasma chamber includes a lower electrode located within an electrostatic chuck (ESC). The system including an upper electrode disposed above the lower electrode. The system including an edge ring surrounding the lower electrode. The system including a first nanosecond direct current (DC) pulsing generator electrically coupled to the lower electrode, and configured for supplying a first low frequency pulsed DC power signal to the lower electrode, wherein the first low frequency pulsed DC power signal is non-sinusoidal. The system including a second nanosecond DC pulsing generator electrically coupled to the edge ring, and configured for supplying a second low frequency pulsed DC power signal to the edge ring. The second low frequency pulsed DC power signal is non-sinusoidal, and is substantially aligned with a frequency and phase and pulse shape of the first low frequency pulsed DC power signal.

Other embodiments of the present disclosure provide for a method for plasma generation. The method including providing a plasma chamber for generating a plasma, wherein the plasma chamber includes a lower electrode located within an electrostatic chuck (ESC). The method including supplying a first low frequency pulsed direct current (DC) power signal to the lower electrode, wherein the first low frequency pulsed DC power signal is non-sinusoidal. The method including supplying a second low frequency pulsed DC power signal to an edge ring surrounding the lower electrode, wherein the second low frequency pulsed DC power signal is non-sinusoidal. The method including substantially aligning the low frequency pulsed DC power signal to a frequency and phase and pulse shape of the low frequency pulsed DC power signal.

These and other advantages will be appreciated by those skilled in the art upon reading the entire specification and the claims.

### BRIEF DESCRIPTION OF THE DRAWINGS

The embodiments may best be understood by reference to the following description taken in conjunction with the accompanying drawings.

FIG. 1 illustrates an embodiment of a capacitive coupled plasma (CCP) processing system utilized for etching operations that is configured for tuning an edge sheath using nanosecond direct current (DC) pulses without corresponding matching networks and that are substantially aligned, in accordance with an implementation of the disclosure.

FIG. 2 illustrates signal measurement locations in the CCP processing system of FIG. 1 for tuning an edge sheath using nanosecond direct current (DC) pulses without corresponding matching networks and that are substantially aligned, in accordance with an implementation of the disclosure.

FIG. 3 is a flow diagram illustrating a method for tuning an edge sheath using nanosecond DC pulsing to the ESC and edge ring, in accordance with one embodiment of the present disclosure.

FIG. 4 illustrates alignment of nanosecond DC pulses of input signals to the ESC and edge ring when tuning an edge sheath, in accordance with one embodiment of the present disclosure.

FIG. 5A illustrates different slopes of voltage signals obtained from measurement of potentials at a substrate and edge ring when a nanosecond DC pulse is not applied to the edge ring when tuning an edge sheath, in accordance with one embodiment of the present disclosure.

FIG. 5B illustrates an alignment of slopes of voltage signals obtained from measurement of potentials at a substrate and edge ring when a nanosecond DC pulse is applied to the edge ring when tuning an edge sheath, in accordance with one embodiment of the present disclosure.

FIGS. 6A-6C illustrate tunability of an edge sheath using nanosecond DC pulsing to the ESC and edge ring, including tuning voltage of the nanosecond DC pulse to tune positioning of the edge sheath over the edge ring, in accordance with one embodiment of the present disclosure.

### DETAILED DESCRIPTION

Although the following detailed description contains many specific details for the purposes of illustration, anyone of ordinary skill in the art will appreciate that many variations and alterations to the following details are within the scope of the present disclosure. Accordingly, the aspects of the present disclosure described below are set forth without any loss of generality to, and without imposing limitations upon, the claims that follow this description.

Generally speaking, the various embodiments of the present disclosure describe methods and apparatus for tuning an edge sheath using nanosecond DC pulses to an ESC and edge ring (e.g., via a coupling ring) without corresponding matching networks, wherein the nanosecond DC pulses are substantially aligned in phase and frequency. In particular, an electrode is placed inside of the coupling ring to receive a nanosecond DC pulse that is capacitively coupled to the edge ring. In addition, a synchronization mechanism (e.g., slave/synchronizing controller) may be configured to control the separate nanosecond DC pulsing sources that provide the nanosecond DC pulses to the ESC and the edge ring. Advantages of the various embodiments include a control mechanism for tuning the edge sheath by adjusting the voltage and/or power of the nanosecond DC pulse signal to the edge ring, wherein the nanosecond DC pulses to the ESC and the edge ring are substantially aligned in phase and frequency. Additional tuning is provided to control a gap between an edge sheath and an edge ring in order to control ion tilt at the edge of a substrate and at the interface between the substrate and edge ring. In that manner, a desired ion tilt at the edge of the substrate and at the substrate/edge ring interface is achieved.

With the above general understanding of the various embodiments, example details of the embodiments will now be described with reference to the various drawings. Similarly numbered elements and/or components in one or more figures are intended to generally have the same configuration and/or functionality. Further, figures may not be drawn to scale but are intended to illustrate and emphasize novel concepts. It will be apparent, that the present embodiments may be practiced without some or all of these specific details. In other instances, well-known process operations have not been described in detail in order not to unnecessarily obscure the present embodiments.

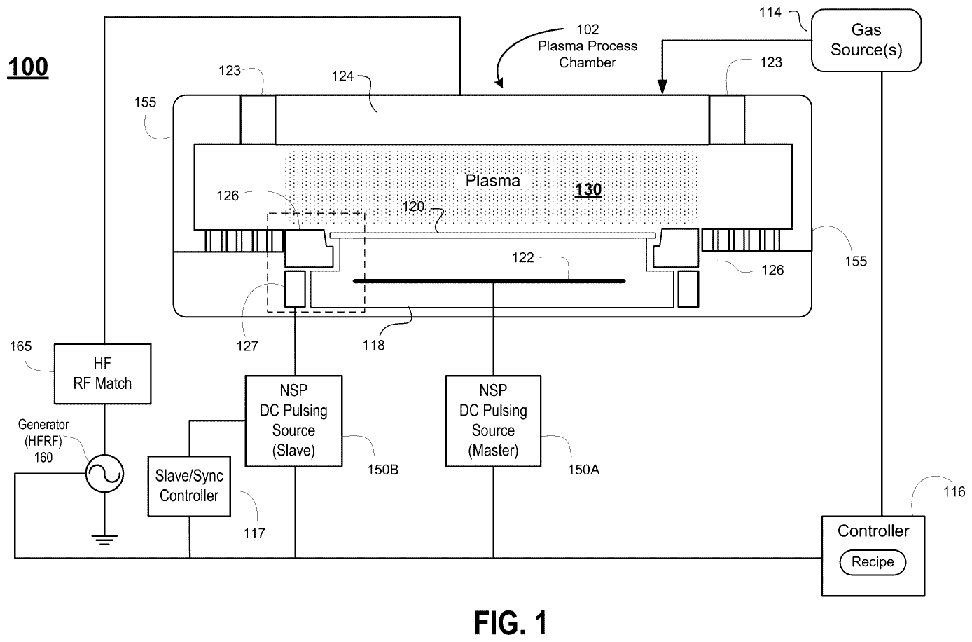

FIG. 1 illustrates an embodiment of a capacitive coupled plasma (CCP) processing system 100 utilized for etching operations that is configured for tuning an edge sheath using nanosecond direct current (DC) pulses without corresponding matching networks and that are substantially aligned, in accordance with an implementation of the disclosure. Generally, exemplary CCP processing system 100 can be utilized for operations including etching and/or depositing films, such as for operations used to perform plasma processing of a substrate 120.

In particular, FIG. 1 illustrates an exemplary embodiment of the plasma processing system 100 utilized for etching operations that is configured as a CCP processing system, and includes a CCP plasma process chamber 102 that is configured for generating plasma. The plasma process chamber 102 includes a substrate support or pedestal, such as an electrostatic chuck (ESC) 118. In embodiments, the ESC may have several circular rings with different material types to achieve a certain capacitive coupling between the ESC and a powered edge ring. A lower electrode 122 may be embedded within the ESC 118. A substrate 120 may be placed on the pedestal for processing, wherein the substrate or wafer 120 is processed to make one or more semiconductor chips. Facing the pedestal is an upper electrode 124, such that the upper electrode is disposed over the lower electrode. The upper electrode 124 may be configured with an extension 123 that may be shaped as a ring. Between the upper electrode 124 and the lower electrode 122 is a gap forming a processing volume within which a plasma 130 may be formed.

In particular, plasma processing system 100 includes a radio frequency (RF) power source 160, and nanosecond pulsed direct current (DC) power generators or sources 150A and 150B, as will be more fully described below. As shown, the upper electrode 124 is coupled to an RF power generator or source 160 (e.g., supplying high frequency RF power, etc.). In addition, the pulsed DC power sources 150A and 150B generally provide power to the ESC 118 or an edge ring 126 via nanosecond pulsed DC signals.

The plasma process chamber 102 also includes the edge ring 126, such as a tunable edge sheath (TES) ring, which surrounds the ESC 118 and/or the lower electrode 122. As an example, the edge ring 126 is fabricated from a conductive material, such as silicon, boron doped single crystalline silicon, silicon carbide, an alloy of silicon, or a combination thereof. It should be noted that the edge ring 126 has an annular body, such as a circular body, or ring-shaped body, or dish-shaped body. As an illustration, the edge ring 126 has an inner radius and an outer radius, and the inner radius is greater than a radius of the ESC 118. The edge ring 126 performs many functions including positioning the substrate 120 on the ESC 118, confining plasma to an area above the substrate 120, protecting the ESC 118 from erosion by ions of the plasma, and shielding underlying components of the plasma chamber 102 from being damaged by ions of the plasma. Further, the edge ring is configured to improve performance at the edge of the substrate. For example, by varying an amount of the power coupled to the edge ring, plasma density of the plasma at the edge region, sheath uniformity of the plasma at the edge region; etch rate uniformity of the plasma at the edge region, and ion tilt at which the substrate is etched in the edge region may be controlled.

As shown, plasma processing chamber 102 of FIG. 1 may include a C-shroud 155 that extends from the upper electrode 124 to the ESC 118 including the bottom electrode to provide additional plasma containment. The C-shroud may have a plurality of apertures to allow gas and byproducts to flow out of the C-shroud. The C-shroud may be grounded. In other embodiments, the plasma processing chamber may be configured differently to include confinement rings (not shown) for confining plasma 130 during etching operations.

In another embodiment, gas source(s) 114 are connected to the plasma process chamber 102 and are configured to inject the desired process gas(es) into the plasma process chamber 102. As an example of plasma formation, after providing one or more RF signals to the upper electrode 124 and/or the ESC 118 and injecting process gas(es) into the plasma process chamber 102, plasma 130 is then formed between the upper electrode 124 and the ESC 118. The plasma 130 can be used to etch the surface of the substrate 120.

As previously introduced, the plasma processing system 100 includes multiple power sources including a high frequency RF power generator or source 160, and nanosecond DC pulsing generator or source 150A and nanosecond DC pulsing generator or source 150B.

As shown, the upper electrode 124 is coupled to RF power source 160 (e.g., supplying high frequency RF power, etc.). The high frequency RF power signal is routed through an impedance match network 165 before being delivered to the upper electrode 124. The match network 165 enables dynamic tuning of power provided to the upper electrode 124 by matching impedance between the load (e.g., plasma chamber and any connecting cabling) and a source (e.g., HFRF generator or source 160 and any connecting cabling). In general, the RF power source 160 provides power via sinusoidal signals (i.e., varying voltage signals in sinusoidal form), which may be pulsed or non-pulsed. For example, RF power source 160 may be a high frequency (HF) RF generator (HFRF), which may be configured to produce high frequencies ranging from and including thirteen (13) megahertz (MHz) to one-hundred twenty (120) MHz. For example, the high frequency can be configured as a baseline frequency of 13.56 MHz or 27 MHz or 40 MHz or 60 MHz or 100 MHz.

In addition, the pulsed DC power sources 150A and 150B generally provide power to the ESC 118 or an edge ring 126 via nanosecond pulsed DC signals. For example, a constant voltage DC signal may be pulsed to provide pulsed DC signals. Pulsed DC power may provide certain advantages over RF power, such as using less power and not requiring an impedance match network (i.e., as implemented through high voltage cabling and/or filter and/or snubber circuits, etc.).

In particular, nanosecond DC pulsing source 150A is electrically coupled to the lower electrode 122, and is configured for supplying a low frequency pulsed DC power signal to the lower electrode to generate plasma, wherein the upper electrode 124 is coupled to the high frequency RF power source 160. The low frequency pulsed DC power signal is matchless, as previously described. Also, the low frequency pulsed DC power signal is non-sinusoidal. In general, the nanosecond DC pulsing source 150A is configured to provide a pulsed DC signal that is pulsed at low frequencies ranging, for example, between ten (10) to eight hundred (800) kHz, and with a duty cycle of less than 50 percent. For example, the frequency of operation of the nanosecond DC pulsing source 150A is 200 kHz or 400 kHz. Also, the pulse width of the pulsed DC signal may range between two hundred (200) to one thousand (1000) nanoseconds.

For example, the pulse width of the pulsed DC signal may be 300 nanoseconds. In one embodiment, the pulse shape of the pulsed DC signal is a square wave. In another embodiment, the nanosecond DC pulsing source 150A is configured as a master power device when used in a master and slave relationship with another DC power source.

Because the power supplied to the lower electrode 122 is decoupled from the power supplied to the upper electrode 124, there is no need for a filter circuit (e.g., between the lower electrode 122 and the nanosecond DC pulsing source 150A), for example to reduce and/or remove any high frequency harmonics, such as those from a high frequency power source. That is, because the DC pulsing source 150A (e.g., to the lower electrode 122) is decoupled from the high frequency RF power source 160 (e.g., to the upper electrode 124), there is no need for a filter circuit. Further, the DC current and the DC power generated by the nanosecond DC pulsing source 150A is decoupled from the DC current and the DC power generated by the 150B. That is, the potential or voltage signal measured at the TES edge ring 126 is decoupled from the nanosecond DC pulsing source 150A providing power to the lower electrode 122 of the ESC 118. In addition, the coupling between the nanosecond DC pulsing source 150A and the lower electrode 122 is matchless, in one embodiment.

In addition, nanosecond DC pulsing source 150B is electrically coupled to the TES edge ring 126 via a coupling ring 127 that is adjacent to the edge ring. In particular, the nanosecond DC pulsing source 150B is configured for supplying a low frequency pulsed DC power signal to the TES edge ring 126. The low frequency pulsed DC power signal is matchless, as previously described. Also, the low frequency pulsed DC power signal is non-sinusoidal. In particular, the low frequency pulsed DC power signal may be delivered to an electrode 250 embedded within the coupling ring 127, such as via a power pin 128. That is, the coupling ring is configured to receive the low frequency pulsed DC power signal, such as via electrode 250. Further, the low frequency pulsed DC power signal is delivered to the TES edge ring 126 via capacitive coupling between the coupling ring and the edge ring.

The nanosecond DC pulsing source 150B is configured as a slave power device when used in a master and slave relationship with another DC power source, such as nanosecond DC pulsing source 150A. In general, and similar to the DC pulsing source 150A, the nanosecond DC pulsing source 150B is configured to provide a pulsed DC signal that is pulsed at low frequencies ranging, for example, between ten (10) to eight hundred (800) kHz, and with a duty cycle of less than 50 percent. For example, the frequency of operation of the nanosecond DC pulsing source 150B is 200 kHz or 400 kHz. Also, the pulse width of the pulsed DC signal may range between two hundred (200) to one thousand (1000) nanoseconds. For example, the pulse width of the pulsed DC signal may be 300 nanoseconds. In one embodiment, the pulse shape of the pulsed DC signal is a square wave.

Because the power supplied to the edge ring 126 (e.g., via the coupling ring 127) is decoupled from the power supplied to the upper electrode 124, there is no need for a filter circuit (e.g., between the edge ring 126 and/or the coupling ring 127 and the nanosecond DC pulsing source 150B) to reduce and/or remove any high frequency harmonics, such as those from a high frequency power source. That is, because the DC pulsing source 150B (e.g., to the edge ring 126 and/or the coupling ring 127) is decoupled from the high frequency RF power source 160 (e.g., to the upper electrode 124), there is no need for a filter circuit. Further, the DC current and the DC power generated by the nanosecond DC pulsing source 150B is decoupled from the DC current and the DC power generated by the 150A. That is, the potential or voltage signal measured at the substrate 120 is decoupled from the nanosecond DC pulsing source 150B providing power to the TES edge ring 126 (i.e., via the coupling ring 127). In addition, the coupling between the nanosecond DC pulsing source 150B and the edge ring 126 and/or the coupling ring 127 is matchless, in one embodiment.

In one embodiment, the low frequency pulsed DC power signal delivered to the TES edge ring 126 (e.g., via coupling ring 127) is substantially aligned with the low frequency pulsed DC power signal delivered to the ESC 118. In particular, the frequency and phase and pulse shape of the two low frequency pulsed DC power signals to the ESC and the TES edge ring are substantially aligned. Further, because of the master and slave relationship between the nanosecond DC pulsing sources 150A and 150B, the frequency and phase and pulse shape of the low frequency pulsed DC power signal delivered to the TES edge ring is substantially aligned to the frequency and phase and pulse shape of the low frequency pulsed DC power signal delivered to the ESC. Alignment between the two low frequency pulsed DC power signals to the ESC and TES edge ring need not be in perfect alignment, as the plasma 130 is configured to equalize the power signals when delivered to the ESC 118 (i.e., and correspondingly to the substrate through capacitive coupling) and the TES edge ring, in one embodiment. That is, the frequency and phase and pulse shape of the measured signals (e.g., voltage signals) at the substrate 120 and the edge ring 126 have been equalized even when the low frequency pulsed DC power signals to the ESC and TES edge ring are not perfectly synchronized and/or matched.

In one embodiment, once the low frequency DC power signals to the ESC the TES edge ring are substantially aligned, control of the power delivered to the edge ring 126 provides for control of the plasma sheath at the edge of the substrate, and correspondingly control of the ion tilt at the edge of the substrate (e.g., an angle substantially normal to the substrate or perpendicular to the substrate, or at other angles to the substrate). For example, control of the power delivered to the edge ring 126 may be implemented through control of the voltage of the low frequency DC power signal generated by the nanosecond DC pulsing source 150B.

In one embodiment, the plasma processing system 100 includes a slave and/or synchronization controller 117 that provides a pulse sync output used for controlling one or more parameters of the low frequency DC power signal generated by the nanosecond DC pulsing source 150B. That is, the slave and/or synchronization controller 117 is configured to substantially align the low frequency pulsed DC power signal delivered to the TES edge ring 126 (e.g., via coupling ring 127) to the low frequency pulsed DC power signal delivered to the ESC 118, including aligning the frequency, phase, and/or pulse shape. In some embodiments, the slave and/or synchronization controller 117 works in combination with the controller 116 to substantially align the two low frequency pulsed DC power signals. In particular, the slave and/or synchronization controller 117 is configured to tune a voltage of the low frequency pulsed DC power signal generated from the nanosecond DC pulsing source 150B until a slope of a measured voltage signal taken from the TES edge ring 126 align with a slope of a measured voltage signal taken from the substrate 120, in one embodiment. In another embodiment, the slave and/or synchronization controller 117 is configured to tune a voltage of the low frequency pulsed DC power signal generated from the nanosecond DC pulsing source 150B until one or more voltages of a measured voltage signal taken from the substrate 120 align with one or more voltages of a measured voltage signal taken from the edge ring 126.

In some embodiments, the nanosecond DC pulsing source 150B is used to substantially align the low frequency pulsed DC power signal delivered to the TES edge ring 126 (e.g., via coupling ring 127) to the low frequency pulsed DC power signal delivered to the ESC 118, including aligning the frequency, phase, and/or pulse shape. That is, there is no need for the slave and/or synchronization controller 117. For example, the DC pulsing source 150B may be in communication with the controller 116 to obtain the parameters of the low frequency pulsed DC power signal delivered to the ESC 118 and generated by the nanosecond DC pulsing source 150A, or may obtain those parameters directly from the nanosecond DC pulsing source 150A for purposes of controlling the low frequency pulsed DC power signal delivered to the TES edge ring 126.

In one embodiment, the plasma processing system 100 having pulsed DC signals driving the ESC 118 and TES edge ring 126 (e.g., via coupling ring 127), the pulsed DC signals can be generated from a single DC pulsing source (i.e., a shared DC pulsing source). That is, the low frequency DC power signals to the ESC 118 the TES edge ring 126 may be substantially aligned and/or synchronized (e.g., frequency, phase, and/or pulse shape) using the single DC pulsing source. For example, there is no time delay between the pulsed DC signals driving the ESC and the TES edge ring. In particular, the shared DC pulsing source may provide multiple pulsed DC signals. For example, shared DC pulsing source may provide one nanosecond pulsed DC signal to drive the lower electrode 122 in the ESC 118, and another nanosecond pulsed DC signal to the TES edge ring 126 (e.g., via coupling ring 127). That is, the shared DC pulsing source provides separate pulsed DC signals to drive the edge ring 126 and the ESC 118. In one embodiment, the use of a single and/or shared DC pulsing source to drive the ESC 118 and TES edge ring 126 (e.g., via coupling ring 127) negates the use of a synchronization controller (e.g., slave and/or synchronization controller 117).

In some embodiments, the system may include a controller 116 that is used for controlling various components of the plasma processing system 100A. In one example, the controller 116 can be connected to the plasma generators (e.g., high frequency RF source 160, nanosecond DC pulsing source 150A, and nanosecond DC pulsing source 150B), to the gas source(s) 114 that are coupled to the plasma process chamber 102, and to other components. The controller 116 includes a processor, memory, software logic, hardware logic and input and output subsystems from communicating with, monitoring and controlling the plasma processing system 100. In some embodiments, the controller 116 includes one or more recipes including multiple set points and various operating parameters (e.g., voltage, current, frequency, pressure, flow rate, power levels, temperature, timing parameters, process gases, mechanical movement of the substrate 120, etc.) for operating the plasma processing system 100A. For example, depending on the processing being performed, the controller 116 controls the delivery of process gases delivered from the gas source(s) 114 to achieve a designed processing condition, such as to etch features and/or deposit or form films over the substrate 120. The chosen gases are then distributed in a space volume defined between the upper electrode 124 and the substrate 120 resting over the ESC 118.

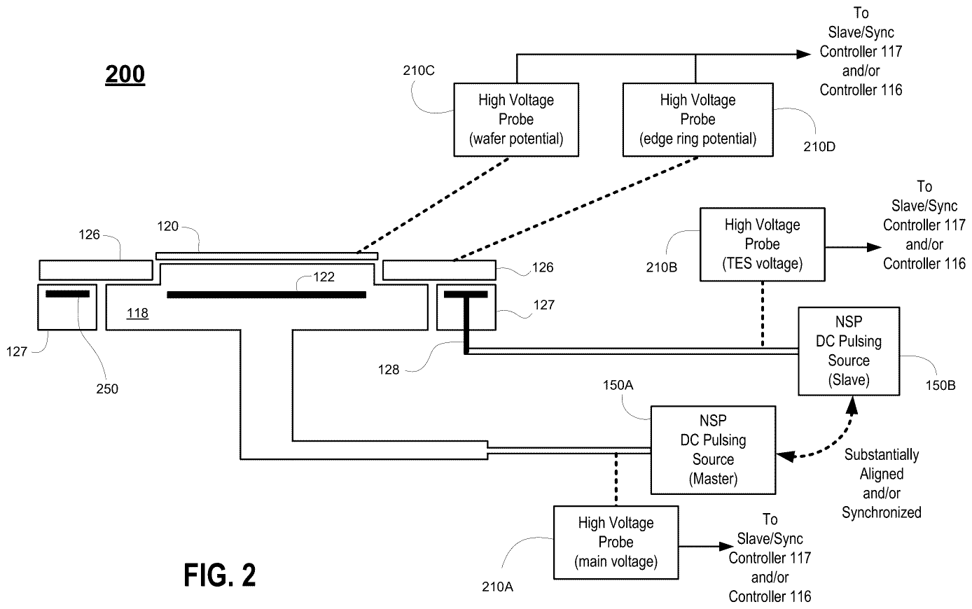

FIG. 2 illustrates a control system 200 that is utilized for achieving control of the plasma sheath at the edge of the substrate, and correspondingly control of the ion tilt at the edge of the substrate (e.g., an angle substantially normal to the substrate or perpendicular to the substrate, or at other angles to the substrate), by measuring power signals (e.g., voltage) at the substrate and edge ring and by controlling power delivered to the edge ring, in accordance with one embodiment of the present disclosure. For example, control of the power delivered to the edge ring 126 may be implemented through control of the voltage of the low frequency DC power signal generated by the nanosecond DC pulsing source 150B shown in FIG. 1. In particular, control system 200 illustrates signal measurement locations in the CCP plasma processing system 100 of FIG. 1 for tuning an edge sheath using nanosecond direct current (DC) pulses without corresponding matching networks and that are substantially aligned, and by control of the power delivered to the edge ring 126. For purposes of illustration, control system 200 may be adapted for implementation within the exemplary plasma processing system 100 of FIG. 1. For example, for purposes of brevity and clarity the control system 200 includes a plasma processing system that is described in FIG. 1 (i.e., CCP plasma processing system 100 including nanosecond DC power sources coupled to the TES edge ring 126 (e.g., via coupling ring 127) and the ESC 118.

In particular, the control system 200 implements a control scheme for controlling the tunable edge ring plasma sheath or TES plasma sheath. As shown, DC power is independently applied to the substrate 120 (e.g., via ESC 118) and to the capacitively coupled edge ring 126 by multiple nanosecond DC pulsing sources 150A and 150B providing pulsed DC signals. For example, nanosecond DC pulsing source 150A (e.g., delivering power to the ESC) may be configured as a master power source with the nanosecond DC pulsing source 150B (e.g., delivering power to the edge ring) configured as a slave power source.

In one embodiment, the frequency and/or phase and/or pulse shape of the nanosecond DC pulsing source 150B (e.g., acting as a slave source) is substantially aligned with the frequency and phase and pulse shape of the nanosecond DC pulsing source 150A (e.g., acting as the master source). In that manner, when the two pulsed DC power sources are substantially aligned, the power and/or voltages at the substrate 120 and the TES edge ring 126 are balanced. With proper balancing, this leads to matching of the slopes for the measured power signals or voltage signals at the substrate 120 and the TES edge ring 126. In other words, the slope of the measured power signal or voltage signal at the substrate 120 aligns with, or is equal to or is substantially equal to, the slope of the measured power signal or voltage signal at the edge ring 126. That is, in the master and slave relationship between the two pulsed DC power sources, the nanosecond DC pulsing source 150B is tuned in order to achieve equalization or matching of the slopes for the measured power signals or voltage signals at the substrate 120 and the TES edge ring 126. With proper balancing, the plasma sheaths over the substrate 120 and the TES edge ring 126 may become coplanar, especially over the interface between the substrate and the TES edge ring. For example, the ion tilt may be perpendicular to the substrate (e.g., 0 degrees) at the interface. In one embodiment, one or more of the parameters to the frequency and/or phase and/or pulse shape of the nanosecond DC pulsing source 150B is or are tuned until the slope of the measured power signal or voltage signal at the substrate 120 aligns with the slope of the measured power signal at the edge ring 126 in order to achieve substantial alignment of the two pulsed DC power sources, and/or proper balancing between the measured power signals or voltage signals at the substrate 120 and the TES edge ring 126.

Without being bound by theory or mechanism of action, and for purposes of clarity, the master and slave power sources need not be perfectly aligned in one embodiment, as it is believed that the plasma sheath 130 equalizes the power signals received at the substrate 120 and the edge ring 126 (e.g., received through capacitive coupling). For example, by having power signals that are aligned, or equal, or matched, at the substrate and the TES edge ring, this may indicate that the power and/or voltages provided by the nanosecond DC pulsing sources delivering pulsed DC power to the lower electrode and the TES edge ring (i.e., via the coupling ring) are balanced at the interface between the substrate and the edge ring. For purposes of illustration when the power and/or the voltages are balanced at the interface, the plasma sheath along and/or over the edge ring may become coplanar with the plasma sheath along and/or over the substrate. This may result in ion tilt or incidences being substantially equal across the interface, especially at the edge of the substrate. For example, ion tilt may be at 0 degrees or perpendicular to the substrate. In that manner, ion angular spread (e.g., ion tilt angles) at the extreme edge of a substrate may be reduced and/or eliminated. That is, the ion tilt at the edge of the substrate may be similar to the ion tilt over the majority of the substrate (e.g., center).

In particular, high voltage probe or measurement sensor 210A can be configured to measure parameters (e.g., voltage, frequency, phase, pulse shape, pulse width, etc.) of the low frequency pulsed DC power signal at the output of the nanosecond DC pulsing source 150A (e.g., master source). Also, high voltage probe or measurement sensor 210B can be configured to measure parameters (e.g., voltage, frequency, phase, pulse shape, pulse width, etc.) of the low frequency pulsed DC power signal at the output of the nanosecond DC pulsing source 150B (e.g., slave source). In some configurations, the corresponding high voltage probe or measurement sensor 210A and/or 210B may be included within the corresponding power source (e.g., voltage sensor located within a nanosecond DC pulsing source 150A and/or 150B) for regulating the same power source.

The measurements from each of the high voltage probe or measurement sensors 210A and/or 210B may be delivered to controller 116, and/or the slave/synchronization controller 117, and/or a power generator configured as a controller for purposes of substantially aligning the power signals, in embodiments. Specifically, after measurements by the high voltage probes or measurement sensors 210A and/or 210B, the frequencies, phase, and/or pulse shape of low frequency pulsed DC power signals from the nanosecond DC pulsing source 150B may be substantially aligned according to the master slave relationship, previously described, as controlled by the controller 116 and/or the slave/synchronization controller 117, in one embodiment.

As previously described, once the low frequency DC power signals to the ESC 118 the TES edge ring 126 are substantially aligned, further control of the power delivered to the edge ring 126 provides for additional tuning of the plasma sheath at the edge of the substrate, and correspondingly control of the ion tilt at the edge of the substrate (e.g., an angle substantially normal to the substrate or perpendicular to the substrate, or at other angles to the substrate). That is, the height of the plasma sheath at the edge of the substrate and/or over the edge ring may be controlled. Correspondingly, controlling the height of the plasma sheath allows for achieving a desired ion tilt from contributions of the plasma sheath over the substrate and the plasma sheath over the edge ring, especially at the interface between the substrate and the edge ring.

For example, control of the power delivered to the edge ring 126 may be implemented through control of the voltage of the low frequency DC power signal generated by the nanosecond DC pulsing source 150B.

In particular, control of the power delivered to the edge ring, for example to control the height of the plasma sheath, can be achieved by measuring one or more parameters of the power signals at the substate 120 and the TES edge ring 126. For example, voltages of power signals at the substate 120 and the TES edge ring 126 can be monitored by voltage pickups (e.g., high voltage probes and/or sensors, etc.). As shown, the control scheme of control system 200 controls parameters of the plasma sheath (e.g., sheaths over the substrate and the edge ring) to achieve a desired ion tilt at the edge of the substrate through measurement of voltages at the substrate and edge ring. In that manner, power of the low frequency DC power signal to the TES edge ring 126 may be adjusted to control the plasma sheath.

As shown, high voltage probe or measurement sensor 210C is placed at a suitable location for measuring one or more parameters (e.g., potential, voltage etc.) of a low frequency pulsed DC power signal received at the substrate 120. For example, measurement sensor 210C may be configured to determine a voltage signal at the substrate 120 (i.e., showing potential or voltage). In addition, high voltage probe or measurement sensor 210D is placed at a suitable location for measuring one more parameters (e.g., potential, voltage, etc.) of a low frequency pulsed DC power signal received at the edge ring 126. For example, measurement sensor 210D may be configured to determine a voltage signal (i.e., showing potential or voltage) at the edge ring 126. Measurements from each of the high voltage probe or measurement sensors 210C and/or 210D may be delivered to controller 116, and/or the slave/synchronization controller 117, and/or a power generator configured as a controller for purposes of controlling one or more parameters or characteristics of the plasma sheath (e.g., sheaths over the substrate and the edge ring), such as controlling the height of the plasma sheath over the substrate and/or the edge ring.

Based on the measurements of the potential at the substrate and the edge ring, deliberate adjustment and/or control of the power of the low frequency DC power signal to the TES edge ring 126 may be performed to control the plasma sheath in order to achieve a desired performance at the edge of the substrate, such as a 0 degree ion tilt that is perpendicular to the substrate at the edge of the substrate and over the edge ring, or a predetermined ion tilt at the edge of the substrate (e.g., at the interface between the substrate and the edge ring). Adjustment of the low frequency DC power signal to the TES edge ring 126 may be controlled by the slave/synchronization controller 116, as previously described. For example, the slave/synchronization controller 116 may be configured to tune a potential and/or voltage of the low frequency DC power signal to the TES edge ring 126 until a slope of the measured power signal or voltage signal at the substrate 120 aligns with a slope of the measured power signal at the edge ring 126. The slave/synchronization controller 116 may be configured to verify that the slopes are aligned in response to substantial alignment of the two low frequency DC power signals to the ESC 118 and the TES edge ring 126 (i.e., via the coupling ring 127). Also, the slave/synchronization controller 116 may be configured to tune a potential and/or voltage of the low frequency DC power signal to the TES edge ring 126 until a potential or voltage of the measured power signal or voltage signal at the substrate 120 aligns with a potential or voltage of the measured power signal at the edge ring 126, in one embodiment.

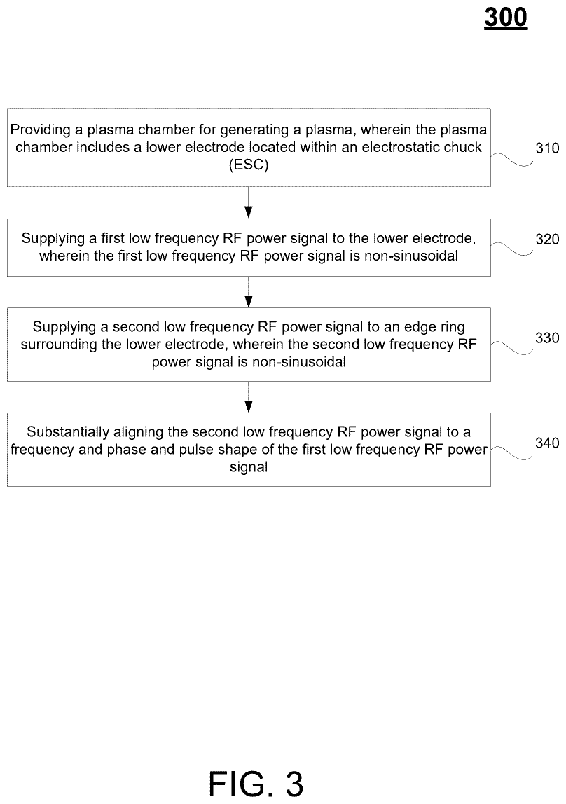

FIG. 3 is a flow diagram 300 illustrating a method for tuning an edge sheath using nanosecond DC pulsing to the ESC and edge ring, in accordance with one embodiment of the present disclosure. The method of flow diagram 300 may be implemented to control processes in the plasma processing system 100 of FIG. 1. For example, the method of flow diagram 300 may be stored in computer-readable form in memory accessible by controller 116, and/or the slave/synchronization controller 117, and/or a power generator configured as a controller of FIGS. 1-2 in order to perform the operations of flow diagram 300. For example, flow diagram 300 may be implemented for purposes of controlling one or more parameters or characteristics of a plasma sheath (e.g., sheaths over the substrate and the edge ring), to include controlling the height of the plasma sheath over the substrate and/or the edge ring, as previously described.

At 310, the method includes providing a plasma chamber for generating a plasma, wherein the plasma chamber includes a lower electrode located within an electrostatic chuck. For example, the plasma chamber may be configured as a CCP chamber, and include, in part, an ESC (e.g., substrate support), a lower electrode embedded within the ESC, an upper electrode disposed over the lower electrode, and an edge ring (e.g., TES edge ring) surrounding the ESC and/or the lower electrode.

Multiple power sources or generators are configured to generate plasma in the plasma chamber. For example, a high frequency RF power source is configured to provide a sinusoidal or alternating current high frequency RF power signal to the upper electrode, as previously described. In addition, one or more nanosecond pulsed DC power sources provide power to the plasma chamber.

At 320, the method includes supplying a low frequency pulsed direct current (DC) power signal to the ESC and/or the lower electrode. The low frequency pulsed DC power signal is non-sinusoidal, and provides power to the ESC and/or the lower electrode via a nanosecond pulsed DC signal (e.g., pulsed at low frequencies). For example, the pulsed DC signal includes a nanosecond pulse waveform having a duty cycle of less than 50 percent. The pulse shape of the pulsed DC signal may be configured as a square wave. In one embodiment, the pulsed DC power signal to the lower electrode is generated by a nanosecond DC pulsing source configured as a master power source when used in a master and slave relationship with another DC power source. For example, the low frequency pulsed DC power signal to the ESC and/or the lower electrode produces sufficient voltage at the ESC to drive positive ions to the substrate due to a negative self-bias action of the substrate.

In addition, the low frequency pulsed DC power signal to the lower electrode is matchless and/or does not require a filter (e.g., high frequency filter), in one embodiment. For example, a nanosecond DC pulsing source and/or generator may be electrically coupled to the lower electrode. The coupling between the nanosecond DC pulsing source and the lower electrode may be matchless and/or without a filter (i.e., filterless) because the power supplied to the lower electrode is decoupled from the high frequency power supplied to the upper electrode. That is, the DC pulsing source to the lower electrode is decoupled from the high frequency RF power source to the upper electrode.

At 330, the method includes supplying another low frequency pulsed DC power signal to the TES edge ring surrounding the lower electrode. The pulsed DC power signal is generated by a nanosecond DC pulsing source that is electrically coupled to the TES edge ring via a coupling ring adjacent to the edge ring. The low frequency pulsed DC power signal is non-sinusoidal, and provides power to the TES edge ring via a nanosecond pulsed DC signal (e.g., pulsed at low frequencies). For example, the pulsed DC signal includes a nanosecond pulse waveform having a duty cycle of less than 50 percent. The pulse shape of the pulsed DC signal may be configured as a square wave.

In addition, the low frequency pulsed DC power signal to the TES edge ring is matchless and/or does not require a filter (e.g., a high frequency filter), in one embodiment. For example, a nanosecond DC pulsing source and/or generator may be electrically coupled to the TES edge ring, such as via a coupling ring adjacent to the edge ring, wherein the pulsed DC power signal is delivered to the TES edge ring via capacitive coupling between the coupling ring and the TES edge ring. The coupling between the nanosecond DC pulsing source and the TES edge ring and/or the coupling ring may be matchless and/or without a filter (i.e., filterless) because the power supplied to the edge ring is decoupled from the high frequency power supplied to the upper electrode. That is, the DC pulsing source to the TES edge ring is decoupled from the high frequency RF power source to the upper electrode.

In one embodiment, the nanosecond DC power source that provides the pulsed DC power signal to the TES edge ring via a coupling ring is configured as a slave power source when used in the master and slave relationship, previously described. In particular, the nanosecond DC pulsing source providing a low frequency pulsed DC power signal to the ESC and/or lower electrode is configured as the master power source, and the nanosecond DC pulsing source providing a low frequency pulsed DC power signal to the TES edge ring via a coupling ring is configured as the slave power source.

At 340, the method includes substantially aligning the low frequency pulsed DC power signal delivered to the TES edge ring (e.g., via the coupling ring) to the low frequency pulsed DC power signal delivered to the lower electrode. In particular, a frequency and/or phase and/or pulse shape of the low frequency pulsed DC power signal delivered to the TES edge ring is substantially aligned with a frequency and/or phase and/or pulse shape of the low frequency pulsed DC power signal delivered to the lower electrode.

For example, the low frequency pulsed DC power signal delivered to the lower electrode is measured at the output of a corresponding nanosecond DC pulsing source. In addition, the low frequency pulsed DC power signal delivered to the TES edge ring (i.e., via a coupling ring) is measured at the output of a corresponding nanosecond DC pulsing source. Measurements of one or more parameters may be determined using one or more high voltage probes or measurement sensors. Measured parameters may include frequency, and/or phase, and/or pulse shape, etc. In that manner, one or more relationships may be determined between the low frequency pulsed DC power signal delivered to the TES edge ring (e.g., via the coupling ring) and the low frequency pulsed DC power signal delivered to the lower electrode. In particular, a frequency relationship may be determined, and/or a phase relationship may be determined, and/or a phase relationship may be determined, and/or a pulse shape relationship may be determined. Based on these relationships, substantial alignment between the two pulsed DC power sources delivering power to the TES edge ring (i.e., via the coupling ring) and the lower electrode may be achieved.

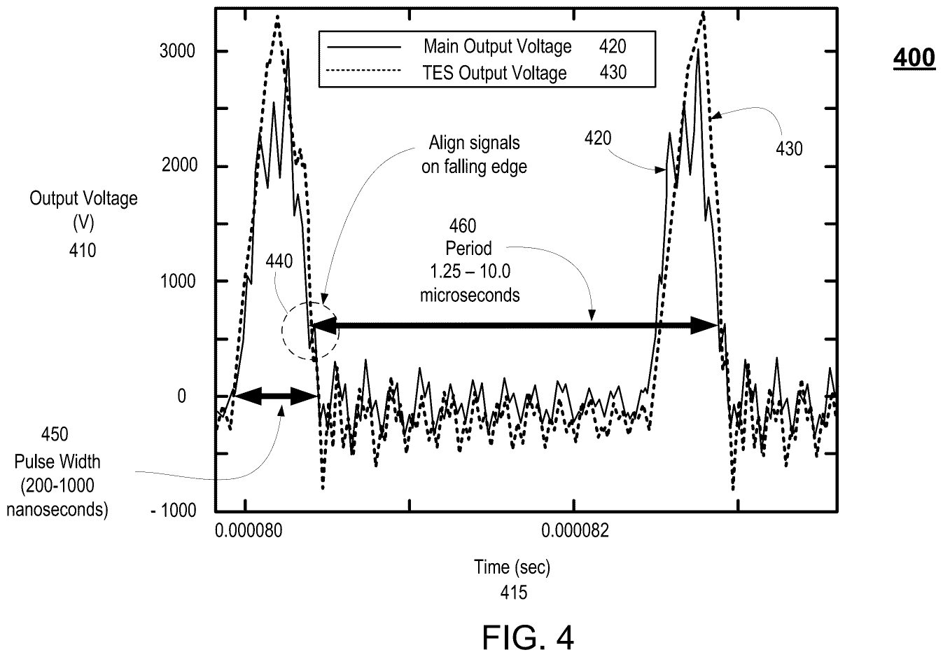

In that manner, when the two pulsed DC power sources are substantially aligned, the power and/or voltages at the substrate (i.e., supported by the ESC) and the TES edge ring are balanced. As previously described, this leads to an alignment or matching or equalization of the slopes for the measured power signals or voltage signals at the substrate and the TES edge ring. That is, the slopes of the measured power signal or voltage signal at the substrate and the TES edge ring are equal or are substantially equal in value. With proper balancing the plasma sheaths over the substrate and the TES edge ring may become coplanar, especially over the interface between the substrate and the TES edge ring. Substantial alignment between the two pulsed DC power sources is illustrated in FIG. 4, as further described below.

In general, it is difficult to meet process specifications at the edge of a substrate due to a tradeoff between a profile angle or ion tilt at which the substrate is etched and an etch rate. Ion tilt and/or etch rate may be influenced by the interaction between the wafer plasma sheath (i.e., plasma over the ESC or substrate) and the edge ring plasma sheath (plasma beyond the edge of the substrate and over the edge ring). It may be beneficial to control the thicknesses of or the plasma densities between the wafer plasma sheath and the edge ring plasma sheath, especially at the interface between the ESC and the edge ring.

In embodiments of the present disclosure, control may be achieved, in part, by balancing the two pulsed DC power sources delivering power to the TES edge ring (i.e., via the coupling ring) and the lower electrode in order to align or match or equalize slopes for the measured power signals or voltage signals at the substrate and the TES edge ring. Balancing of the two pulsed DC power sources may be achieved by substantially aligning one or more parameters (e.g., frequency and/or phase and/or pulse shape) between the low frequency pulsed DC power signals delivered to the TES edge ring and the lower electrode, in one embodiment. Also, balancing of the two pulsed DC power sources may be achieved by aligning or matching or equalizing the slopes for the measured power signals or voltage signals at the substrate and the TES edge ring.

Further control of the thicknesses of or the plasma densities between the wafer plasma sheath and the edge ring plasma sheath may be performed by tuning the power and/or potential of the power signal that is measured at the TES edge ring in order to generate a desired control thickness of the edge ring plasma sheath at the edge of the substrate. In particular, the measured edge ring voltage can be tuned by manipulating the low frequency pulsed DC power signal generated by the nanosecond DC pulsing source delivering power to the TES edge ring, such as by increasing or decreasing the power or voltage of the pulsed DC power signal. In that manner, a desired ion tilt may be achieved from contributions of the wafer plasma sheath and the edge ring plasma sheath (e.g., that is tuned) at the interface, wherein the desired ion tilt is achieved in part through measurement of the power signals (e.g., voltage signals) at the substrate and TES edge ring, and through tuning of the voltage and/or power of the low frequency pulsed DC power signal delivered to the edge ring (i.e., via a coupling ring). That is, by adjusting relative power or voltage between the power signals provided to the ESC and the edge ring, ion tilt can be controlled at the interface between the substrate and the edge ring.

For example, the power signal delivered to the substrate is measured, including measuring potential at the substrate to determine a first voltage signal. In addition, the power signal delivered to the TES edge ring is measured, including measuring potential at the edge ring to determine a second voltage signal. Measurements of one or more parameters of the power signals at the substrate or the TES edge ring may be determined using one or more high voltage probes or measurement sensors. The measured potential at the TES edge ring can be controlled by tuning the power signal generated by the power source delivering power to the edge ring. In one embodiment, the power or voltage of the low frequency pulsed DC power signal generated by the nanosecond DC pulsing source delivering power to the TES edge ring (e.g., via the coupling ring) is tuned until a slope of the first voltage signal measured at the substrate matches, or is equal to, or substantially matches, or is substantially equal to the slope of the second voltage signal measured at the TES edge ring. In another embodiment, the power or voltage of the low frequency pulsed DC power signal generated by the nanosecond DC pulsing source delivering power to the TES edge ring (e.g., via the coupling ring) is tuned until a voltage of the low frequency pulsed DC power signal to the TES edge ring matches a predetermined voltage setpoint, or in another implementation until one or more voltages of the first voltage signal align with one or more voltages of the second voltage signal. In that manner, a desired control thickness of the edge ring plasma sheath at the edge of the substrate may be achieved in order to obtain a desired ion tilt at the interface between the substrate and the TES edge ring. As a result, ion angular spread (e.g., ion tilt angles) at the extreme edge of a substrate is reduced or eliminated. For example, the TES edge ring may experience wear through continued use, such that a decreasing of a thickness of the edge ring may affect the thickness of the edge ring plasma sheath over the edge ring, which affects ion tilt at the interface. Tuning of the power or voltage of the low frequency pulsed DC power signal generated by the nanosecond DC pulsing source delivering power to the TES edge ring (e.g., via the coupling ring) may reduce the effects of the wearing of the TES edge ring with the ability to control a thickness of the edge ring plasma sheath at the edge of the substrate, and correspondingly the ion tilt at the interface.

FIG. 4 illustrates alignment of nanosecond DC pulses of input signals to the ESC and TES edge ring when tuning an edge sheath, in accordance with one embodiment of the present disclosure. Purely for illustration purposes, voltages 410 of the input signals (e.g., y-axis) are measured over time 415 (e.g., x-axis). As shown, the voltage signal 420 (e.g., main power signal) taken at the output of the nanosecond DC pulsing source delivering power to the lower electrode and/or ESC is compared against the voltage signal 430 taken at the output of the nanosecond DC pulsing source delivering power to the TES edge ring (e.g., via a coupling ring).

In particular, the voltage signal 420 (e.g., main power signal delivered to the lower electrode) is a lower frequency pulsed DC power signal that is non-sinusoidal, and is shown by a solid line. For example, the pulsed DC signal is pulsed at low frequencies ranging between 10 to 800 kHz, and/or correspondingly a period 460 between 1.25 to 10 microseconds. The pulsed DC signal has a duty cycle of less than 50 percent, wherein the pulse width 450 of may range between 200 to 1000 nanoseconds. As shown, the pulse shape of the voltage signal 420 is a square wave. In addition, in one embodiment, the pulse is a positive pulse, as is shown in FIG. 4.

As previously described, the voltage signal 430 (e.g., providing power to the TES edge ring via a coupling ring) is substantially aligned with the voltage signal 420 (main power signal delivered to the lower electrode), and is shown by a dotted line. That is, the voltage signal 430 is also a lower frequency pulsed DC power signal that is non-sinusoidal. As shown, the pulse widths 450, and/or the pulse shapes of the pulses, and/or the frequencies or periods 460 are aligned, or substantially aligned, or synchronized between the voltage signals 420 and 430. In one embodiment, the two voltage signals 420 and 430 have identical nanosecond pulse shapes. As such, the pulse widths 450, and/or the pulse shapes of the pulses, and/or the frequencies or periods 460 of the voltage signals 420 and 430 may be controlled, for example to substantially align the voltage signal 430 (delivered to the TES edge ring) to the voltage signal 420 (delivered to the lower electrode) in a master slave relationship, as previously described. As previously described, the two pulsed DC power sources need not be perfectly aligned in one embodiment, as it is believed that the plasma sheath equalizes the power signals received at the substrate and the TES edge ring so that they are balanced at the interface of the substrate and the edge ring.

In one embodiment, the phases of the voltage signals 420 and 430 are aligned, or substantially aligned, or synchronized. In particular, the timing of the falling edge of the voltage signal 430 is substantially aligned with the timing of the falling edge of the voltage signal 420, as is shown by the highlighted area 440, in one embodiment. That is, the phase of the low frequency pulsed DC power signal delivered to the lower electrode of the ESC is aligned with the phase of low frequency pulsed DC power signal delivered to the TES edge ring (e.g., via a coupling ring).

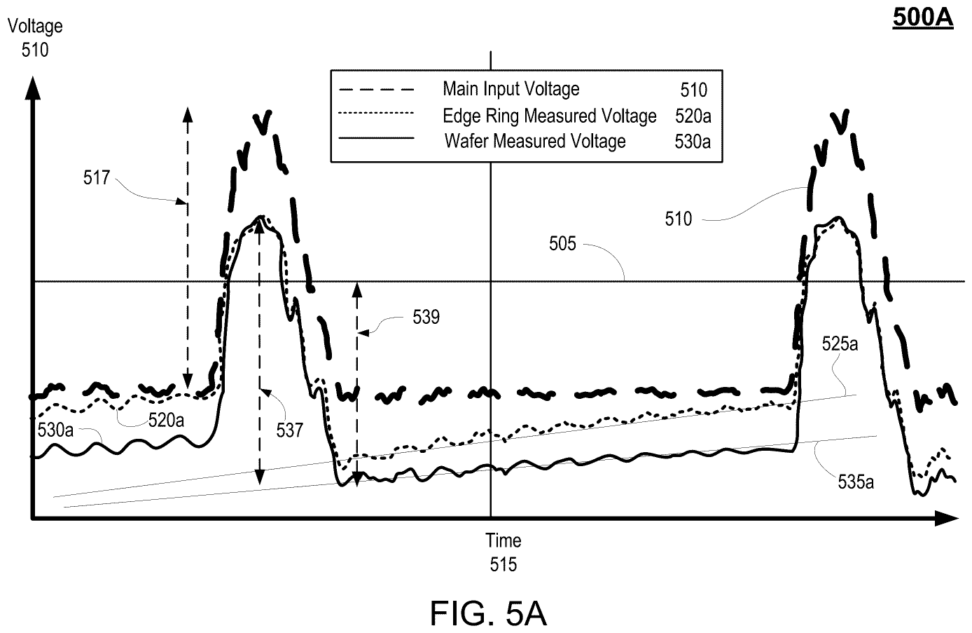

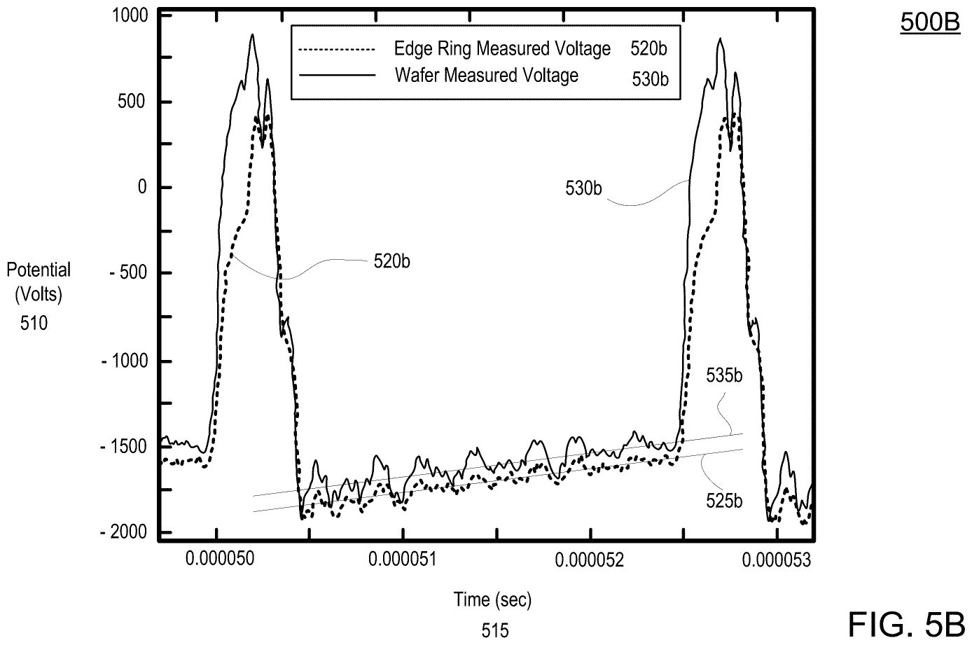

FIGS. 5A and 5B illustrate power signals at various locations in a CCP processing chamber, such as the CCP chamber of FIG. 1. For each of the power signals, voltage is shown along y-axis 510, and time is shown along x-axis 515. The plasma chamber may be configured as a CCP plasma processing system, and includes, in part, an ESC, a lower electrode embedded within the ESC, an upper electrode disposed over the lower electrode, and a TES edge ring surrounding the ESC and/or the lower electrode. Multiple power sources are configured to generate plasma in the CCP plasma processing system, including a high frequency RF power source providing a sinusoidal high frequency RF signal to the upper electrode, and nanosecond pulsed DC power sources providing power to the lower electrode and/or the TES edge ring, as previously described

FIG. 5A illustrates different slopes or droops of voltage signals obtained from measurement of potentials at a wafer and edge ring when a nanosecond DC pulse is not applied to the edge ring when tuning an edge sheath, in accordance with one embodiment of the present disclosure. In particular, three power signals are shown in FIG. 5A wherein voltage (e.g., y-axis 510) is measured with respect to time (e.g., x-axis 515), wherein horizontal line 505 represents zero (0) volts. A main input voltage 510 is shown (e.g., widely spaced dotted line) providing a low frequency pulsed DC power signal delivered to the lower electrode for generating plasma. There is no TES power signal provided to the TES edge ring. Vertical line 517 shows the peak-to-peak voltage of the DC pulse from main input voltage 510. For purposes of illustration, the peak-to-peak voltage may be 3.3 kilovolts and is shown above and below the 0 volt line 505.

Also, a power signal 530a (e.g., shown as a solid line) is measured at the substrate or wafer, wherein the power is delivered from the main input voltage 510 to the substrate via capacitive coupling. Vertical line 537 shows the peak-to-peak voltage of the pulse waveform for the power signal 530a that is measured, which is close to value of the peak-to-peak voltage from the main input voltage 510. Ideally, all of the peak-to-peak voltage from the main input voltage 510 would show up through capacitive coupling in the negative region below the horizontal 0 volt line 505. However, in part, due to voltage division between capacitances of the plasma sheath and the ESC, about 60-80 percent of the full peak-to-peak voltage of the main signal 530a appears at the substrate as a negative voltage (i.e., providing a negative bias on the substrate), which is shown by vertical line 539.

In addition, a power signal 520a (e.g., shown as a tightly spaced dotted line) is measured at the TES edge ring, wherein power from the main input voltage 510 is delivered to the TES edge ring via capacitive coupling with the ESC and/or substrate.

As shown, a slope 535a of the power signal 530a measured at the substrate is different than a slope 525a of the power signal 520a measured at the TES edge ring. Because there is no power signal to the TES edge ring, measured power and/or voltage measured at the substrate and the TES edge ring are not matched or synchronized or equalized, which is indicated by different slopes for the power signals 520a and 530a, and the change in the differences between the power signals 520a and 530a over time between pulses. As such, the plasma sheaths over the substrate and the TES edge ring may be unbalanced. That is, because of the different slopes 525a and 535a the plasma sheaths over the substrate and the TES edge ring are unbalanced or not planar, especially at the interface between the substrate and the TES edge ring.

FIG. 5B illustrates an alignment of slopes or droops of voltage signals obtained from measurement of potentials at a substrate and TES edge ring when a nanosecond DC pulse is applied to the edge ring when tuning an edge sheath, in accordance with one embodiment of the present disclosure. The CCP plasma chamber is powered by at least two power sources, including a low frequency pulsed DC power signal (not shown in FIG. 5B) provided as the main input voltage to the lower electrode in the ESC. Also, in order to tune the power received at the TES edge ring, a low frequency pulsed DC power signal (not shown in FIG. 5B) is delivered to the edge ring (e.g., via a coupling ring). In one embodiment, manipulation of the low frequency pulsed DC power signal (not shown) delivered to the edge ring (e.g., via a coupling ring) provides for tuning of the power signal received at the TES edge ring.

In particular, two power signals are shown in FIG. 5B wherein voltage (e.g., y-axis 510) is measured with respect to time (e.g., x-axis 515). For example, power signal 530b (e.g., shown as a solid line) is measured at the substrate or wafer, wherein the power is delivered from the main input voltage 510 to the substrate via capacitive coupling. Also, power signal 520a (e.g., shown as a tightly spaced dotted line) is measured at the TES edge ring, wherein a main contribution of the measured power at the edge ring may be delivered via capacitive coupling with a coupling ring, wherein a low frequency pulsed DC power signal delivers the power signal to the coupling ring. As shown, the potential (e.g., measured voltage) measured at the TES edge ring is less negative than the potential (e.g., measured voltage) measured that the substrate.

In particular, because the low frequency pulsed DC power signal delivered to the TES edge ring (e.g., via capacitive coupling) is substantially aligned with the low frequency pulsed DC power signal delivered to the lower electrode, as previously described, the measured power and/or potential or voltage measured at the substrate and the TES edge ring are matched and/or are synchronized and/or are equalized. That is, the plasma sheaths over the substrate and the TES edge ring may be balanced, which may indicate that the plasma sheaths are coplanar especially at the interface between the substrate and the TES edge ring. For example, this balance between the plasma sheaths may be shown by a slope 535b of the power signal 530b measured at the substrate being similar to, or equal to, aligned with, or substantially equal to, the slope 525b of the power signal 520b measured at the TES edge ring. Also, because the slopes 525b and 535b are matched, the delta change in the voltage difference between the power signals 520b and 530b remains relatively constant.

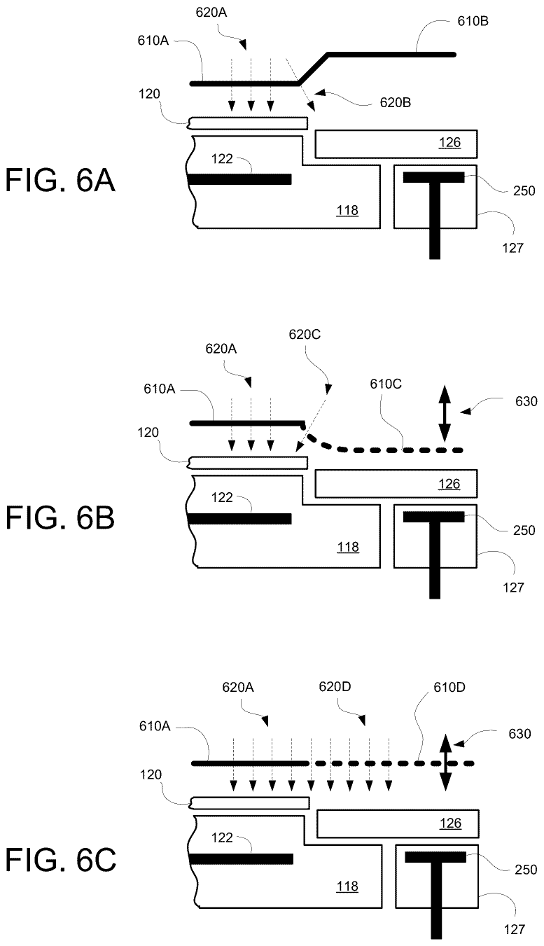

Also, the measured voltage at the TES edge ring may be tuned through manipulation of the power and/or the voltage of the low frequency pulsed DC power signal (not shown) delivered to the edge ring (e.g., via a coupling ring). Tunability may be achieved at low power, wherein the power of the low frequency pulsed DC power signal provided to the TES edge ring (e.g., via the coupling ring) may be 5 to 20 percent of the power of the low frequency pulsed DC power signal provided to the lower electrode. For example, by adjusting the power and/or the voltage, the power signal 525b as measured at the TES edge ring may be moved vertically up or down. In one embodiment, the power and/or voltage of the low frequency pulsed DC power signal (not shown) delivered to the edge ring (e.g., via a coupling ring) may be adjusted so that the power signals 520b (measured at the TES edge ring) and 530b (measured at the substrate) lay on top of each other, for example to achieve a desired ion tilt at the interface between the substrate and the TES edge ring (e.g., 0 degree tilt, or some other value). That is, the lines measuring slopes 525b and 535b may lie on top of each other and may be indistinguishable. In another embodiment the power and/or voltage of the low frequency pulsed DC power signal (not shown) delivered to the edge ring (e.g., via a coupling ring) may be adjusted so that the power signal 520b (measured at the TES edge ring) is at a predefined location with respect to (e.g., above or below) the power signal 530b (measured at the substrate). In that manner, a desired ion tilt at the interface between the substrate and the TES edge ring may be achieved (e.g., 0 degree tilt, or some other value). This tunability may become useful as the TES edge ring wears away through use, wherein the wearing affects the ion tilt and/or ion spread at the interface between the substrate and the TES edge ring. Typically, as the TES edge ring wears, the plasma sheath over the edge ring lowers in relation to the plasma sheath over the substrate, as is shown in FIG. 6B. Adjusting the power and/or voltage of the low frequency pulsed DC power signal (not shown) delivered to the edge ring (e.g., via a coupling ring) provides for tuning of the height of the plasma sheath over the edge ring, for example to push the sheath over the edge ring upwards in relation to the sheath over the substrate, such that the two plasma sheaths become coplanar.

FIGS. 6A-6C illustrate tunability of an edge sheath using nanosecond DC pulsing to the ESC and edge ring, including tuning voltage of the nanosecond DC pulse to tune positioning of the edge sheath over the edge ring, in accordance with one embodiment of the present disclosure. For example, plasma processing may be performed by a CCP plasma chamber that is powered by at least two power sources, including a low frequency pulsed DC power signal provided as the main input voltage to a lower electrode 122 in an ESC 118 that is configured to support a substrate 120, and a low frequency pulsed DC power signal provided to the TES edge ring 126 (e.g., through capacitive coupling with a coupling ring), wherein power is delivered to an electrode 250 in a coupling ring 127. A high frequency RF power signal may be delivered to an upper electrode disposed opposite the ESC. During processing, a wafer plasma sheath is formed over the substrate or wafer, and an edge ring plasma sheath is formed over the TES edge ring. The CCP plasma chamber may be the chamber 100 illustrated in FIG. 1.

FIG. 6A illustrates unbalanced plasma sheaths at the interface between the substrate and the TES edge ring. For example, the wafer plasma sheath 610A is shown over the substrate 120, and the edge ring plasma sheath 610B is shown over the TES edge ring 126. As shown, the wafer plasma sheath 610A is not coplanar with the edge ring plasma sheath 610B. That is, the plasma sheaths are unbalanced such that the lower surface of the wafer plasma sheath 610A is at a different level than a lower surface of the edge ring plasma sheath 610B, or is not coplanar. This may be due to misalignment between the low frequency pulsed DC power signals delivered to the substrate 120 and the TES edge ring (via the coupling ring), such that the measured power signals at the substrate 120 and the TES edge ring 126 are misaligned. As a result, the ion tilt 620B at the interface between the substrate 120 and the TES edge ring 126 may be angled and/or different than the ion tilt 620A over the substrate 120, which may result in an increase in ion spread at the edge of the substrate. Purely for illustration, the ion tilt 620B at the interface between the substrate 120 and the TES edge ring 126 may direct ions away from the center of the substrate 120.

FIG. 6B illustrates unbalanced plasma sheaths at the interface between the substrate and the TES edge ring that may be due to wear on the TES edge ring 126. This may be due to wear on the edge ring even when the low frequency pulsed DC power signals to the lower electrode and the TES edge ring are substantially aligned, or may be due to misalignment between the low frequency pulsed DC power signals to the lower electrode and the TES edge ring.

The wafer plasma sheath 610A is shown over the substrate 120, and the edge ring plasma sheath 610C is shown over the TES edge ring 126. For example, because of wear on the TES edge ring, the edge ring plasma sheath 610C over the TES edge ring 126 is lower than the wafer plasma sheath 610A over the substrate 120. That is, even when the low frequency pulsed DC power signal to the TES edge ring and the low frequency pulsed DC power signal to the lower electrode are substantially aligned, the plasma sheaths may be unbalanced or not coplanar. Typically, as the TES edge ring 126 wears, the edge ring plasma sheath 610C over the edge ring lowers in relation to the plasma sheath 610A over the substrate. As a result, the ion tilt 620C at the interface between the substrate 120 and the TES edge ring 126 may be angled and/or different than the ion tilt 620A (nearly vertical) over the substrate 120, which may result in an increase in ion spread at the edge of the substrate. Purely for illustration, the ion tilt 620C at the interface between the substrate 120 and the TES edge ring 126 may direct ions towards the center of the substrate 120.

In one embodiment, manipulation of the low frequency pulsed DC power signal (not shown) delivered to the TES edge ring 126 (e.g., via a coupling ring) provides for tuning of the power signal measured and/or received at the TES edge ring 126. In that manner, the height of the edge ring plasma sheath over the TES edge ring 126 may be vertically raised or lowered with respect to the surface of the edge ring, as is shown by directional arrow 630, as shown in FIG. 6C and further described below.

FIG. 6C illustrates balanced plasma sheaths at the interface between the substrate and the TES edge ring 126. In particular, the low frequency pulsed DC power signal to the TES edge ring and the low frequency pulsed DC power signal to the lower electrode are substantially aligned. In that manner, the plasma sheaths over the substrate and the TES edge ring may be balanced or coplanar. Further tuning of the edge ring plasma sheath 610D over the TES edge ring 126 as shown by vertical line 630 may be performed by manipulation of the low frequency pulsed DC power signal (not shown) delivered to the edge ring (e.g., via a coupling ring) to tune the power and/or potential (e.g., voltage signal) measured at the TES edge ring 126. In particular, adjusting the low frequency pulsed DC power signal (not shown) delivered to the TES edge ring 126 is performed to align the height of the edge ring plasma sheath 610D with the height of the wafer plasma sheath 610A. That is, the plasma sheaths over the substrate 120 and the TES edge ring 126 are coplanar. For example, wafer plasma sheath 610A is shown over the substrate 120, and the edge ring plasma sheath 610D is shown over the TES edge ring 126. The ion tilt 620A over the substrate 120 is nearly vertical. In addition, the ion tilt 620D at the interface between the substrate 120 and the TES edge ring 126, as well as over the edge ring, is also nearly vertical. More particular, the ion tilt at the interface between the substrate 120 and the TES edge ring 126 is aligned with the ion tilt 620A over the substrate.

In embodiments of the present disclosure, an apparatus is described. The apparatus includes an electrostatic chuck (ESC). The apparatus includes a lower electrode located within the ESC, wherein a first low frequency pulsed direct current (DC) power signal is applied to the lower electrode. The apparatus includes an edge ring surrounding the ESC and the lower electrode. The apparatus includes a coupling ring located below the edge ring and including a tunable edge sheath (TES) electrode, wherein a second low frequency pulsed DC power signal is applied to the TES electrode and is capacitively coupled to the edge ring. In the apparatus, the second low frequency pulsed DC power signal is substantially aligned with a frequency and a phase and a pulse shape of the first lower frequency pulsed DC power signal.

In the apparatus, the first low frequency pulsed DC power signal is non-sinusoidal, and the second low frequency pulsed DC power signal is non-sinusoidal, in accordance with embodiments of the present disclosure.

The apparatus includes a second nanosecond DC pulsing generator electrically coupled to the TES electrode, and configured for supplying the second low frequency pulsed DC power signal, in accordance with one embodiment of the present disclosure. A second coupling between the second nanosecond pulsing generator and the TES electrode is matchless.

The apparatus including the second nanosecond DC pulsing generator further includes a first nanosecond DC pulsing generator electrically coupled to the lower electrode, and configured for supplying the first low frequency pulsed DC power signal, in accordance with one embodiment of the present disclosure. A first coupling between the first nanosecond pulsing generator and the lower electrode is matchless.

In the apparatus including the first nanosecond DC pulsing generator and the second nanosecond DC pulsing generator, the first nanosecond DC pulsing generator is configured as a master, and the second nanosecond DC pulsing generator is configured as a slave.

The apparatus including first measurement sensor for measuring a potential at a substrate supported by the ESC, wherein the first measurement sensor is configured to determine a first voltage signal, in accordance with one embodiment of the present disclosure. The apparatus includes second measurement sensor for measuring potential at the edge ring, wherein the second measurement sensor is configured to determine a second voltage signal. The apparatus includes a slave controller that is configured to tune a voltage of the second low frequency pulsed DC power signal until a second slope of the second voltage signal substantially matches a first slope of the first voltage signal.

The apparatus including first measurement sensor for measuring potential at a substrate supported by the ESC, wherein the first measurement sensor is configured to determine a first voltage signal, in accordance with one embodiment of the disclosure. The apparatus includes second measurement sensor for measuring potential at the edge ring, wherein the second measurement sensor is configured to determine a second voltage signal. The apparatus includes a slave controller that is configured to tune a voltage of the second low frequency pulsed DC power signal until one or more voltages of the first voltage signal align with one or more voltages of the second voltage signal, or until the voltage of the second low frequency pulsed DC power signal matches a predetermined voltage setpoint.

In the apparatus, the first low frequency pulsed DC power signal is configured as a square pulse with a duty cycle of less than 50 percent, in accordance with one embodiment of the present disclosure.

In the apparatus, first low frequency pulsed DC power signal is configured to have a frequency between 100-800 kilohertz, in accordance with one embodiment of the present disclosure.

In embodiments of the present disclosure, an method is described. The method includes applying a first low frequency pulsed direct current (DC) power signal to a lower electrode located within an electrostatic chuck (ESC). The method includes applying a second low frequency pulsed DC power signal to a tunable edge sheath (TES) electrode located within a coupling ring. The method includes substantially aligning the second low frequency pulsed DC power signal to a frequency and a phase and a pulse shape of the first lower frequency pulsed DC power signal. In the method, the coupling ring is located below an edge ring that surrounds the ESC and the lower electrode. In the method, the second low frequency pulsed DC power signal is capacitively coupled to the edge ring.

In the method, the first low frequency pulsed DC power signal is non-sinusoidal, and the second low frequency pulsed DC power signal is non-sinusoidal, in accordance with embodiments of the present disclosure.

The method further including measuring a first potential at a substrate supported by the ESC to determine a first voltage signal, in accordance with one embodiment of the present disclosure. The method further including measuring a second potential at the edge ring to determine a second voltage signal. The method further including tuning a voltage of the second low frequency pulsed DC power signal until a second slope of the second voltage signal substantially matches a first slope of the first voltage signal.

The method further including measuring a first potential at a substrate supported by the ESC to determine a first voltage signal in accordance with one embodiment of the present disclosure. The method further including measuring a second potential at the edge ring to determine a second voltage signal. The method further including turning a voltage of the second low frequency pulsed DC power signal to match a predetermined voltage setpoint.

The method further including electrically coupling a first nanosecond DC pulsing generator to the lower electrode, wherein the first nanosecond DC pulsing generator is configured for supplying the first low frequency pulsed DC power signal, in accordance with one embodiment of the present disclosure. The method including electrically coupling a second nanosecond DC pulsing generator to the TES electrode, wherein the second nanosecond DC pulsing generator is configured for supplying the second low frequency pulsed DC power signal. In the method, the coupling between the first nanosecond pulsing generator and the lower electrode is matchless. In the method, the coupling between the second nanosecond pulsing generator and the TES electrode is matchless.

In the method including electrical coupling of the first nanosecond DC pulsing generator to the lower electrode and electrical coupling of the second nanosecond TES pulsing generator to the TES electrode, the first nanosecond DC pulsing generator is configured as a master, and the second nanosecond DC pulsing generator is configured as a slave, in accordance with one embodiment of the present disclosure.

In the method, the first low frequency pulsed DC power signal is configured as a square pulse with a duty cycle of less than 50 percent, in accordance with one embodiment of the present disclosure.

In the method, the first low frequency pulsed DC power signal is configured to have a frequency between 100-800 kilohertz In embodiments, a substrate positioning program may include program code for controlling chamber components that are used to load the substrate onto a pedestal or chuck or ESC and to control the spacing between the substrate and other parts of the chamber such as a gas inlet and/or target, which may be implemented by control system 116 or controller of FIGS. 1 and 2. In some implementations, a controller is part of a system, which may be part of the above-described examples. Such systems can comprise semiconductor processing equipment, including a processing tool or tools, chamber or chambers, a platform or platforms for processing, and/or specific processing components (a substrate pedestal, a gas flow system, etc.). These systems may be integrated with electronics for controlling their operation before, during, and after processing of a semiconductor wafer or substrate. The controller, depending on the processing requirements and/or the type of system, may be programmed to control any of the processes disclosed herein, and process implemented for operating a plasma chamber. Program instructions may be instructions communicated to the controller in the form of various individual settings (or program files), defining operational parameters for carrying out a particular process on or for a semiconductor substrate or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” of all or a part of a fab host computer system, which can allow for remote access of the substrate processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, a plasma enhanced chemical vapor deposition (PECVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

Although the foregoing embodiments have been described in some detail for purposes of clarity of understanding, it will be apparent that certain changes and modifications can be practiced within the scope of the appended claims. Accordingly, the present embodiments are to be considered as illustrative and not restrictive, and the embodiments are not to be limited to the details given herein, but may be modified within their scope and equivalents of the claims.

1. A system, comprising:
a plasma chamber configured for generating plasma, wherein the plasma chamber includes a lower electrode located within an electrostatic chuck (ESC);
an upper electrode disposed above the lower electrode;
an edge ring surrounding the lower electrode;
a first nanosecond direct current (DC) pulsing generator electrically coupled to the lower electrode, and configured for supplying a first low frequency pulsed DC power signal to the lower electrode, wherein the first low frequency pulsed DC power signal is non-sinusoidal; and
a second nanosecond DC pulsing generator electrically coupled to the edge ring, and configured for supplying a second low frequency pulsed DC power signal to the edge ring,
wherein the second low frequency pulsed DC power signal is non-sinusoidal, and is substantially aligned with a frequency and phase and pulse shape of the first low frequency pulsed DC power signal.

2. The system of claim 1, further comprising:
a first measurement sensor for measuring potential at a substrate to determine a first voltage signal;
a second measurement sensor for measuring potential at the edge ring to determine a second voltage signal;
a slave controller that is configured to tune a voltage of the second low frequency pulsed DC power signal until a second slope of the second voltage signal substantially matches a first slope of the first voltage signal.

3. The system of claim 1,
a first measurement sensor for measuring potential at a substrate to determine a first voltage signal;
a second measurement sensor for measuring potential at the edge ring to determine a second voltage signal;
a slave controller that is configured to tune a voltage of the second low frequency pulsed DC power signal until one or more voltages of the first voltage signal align with one or more voltages of the second voltage signal.

4. The system of claim 1, further comprising:
wherein the first nanosecond DC pulsing generator is configured as a master,
wherein the second nanosecond DC pulsing generator is configured as a slave.

5. The system of claim 1, further comprising:
a radio frequency (RF) generator electrically coupled to the upper electrode, and configured for supplying a high frequency RF power signal to the upper electrode, wherein the high frequency RF power signal is sinusoidal.

6. The system of claim 1,
wherein a first coupling between the second nanosecond DC pulsing generator and the edge ring is matchless,
wherein a second coupling between the first nanosecond DC pulsing generator and the lower electrode is matchless.

7. The system of claim 1,
wherein the first low frequency pulsed DC power signal is configured as a square pulse with a duty cycle of less than 50 percent.

8. The system of claim 7,
wherein the square pulse has a width between 200-1000 nanoseconds,
wherein the square pulse is the pulse shape.

9. The system of claim 1,
wherein the first low frequency pulsed DC power signal is configured to have a frequency between 100-800 kHz.

10. The system of claim 1, further comprising:
a coupling ring adjacent to the edge ring,
wherein the coupling ring is configured to receive the second low frequency pulsed DC power signal,
wherein the second low frequency pulsed DC power signal is delivered to the edge ring via capacitive coupling between the coupling ring and the edge ring.

11. The system of claim 1,
wherein the plasma chamber is configured as a capacitively coupled plasma chamber.

12. A method, comprising:
providing a plasma chamber for generating a plasma, wherein the plasma chamber includes a lower electrode located within an electrostatic chuck (ESC);
supplying a first low frequency pulsed direct current (DC) power signal to the lower electrode, wherein the first low frequency pulsed DC power signal is non-sinusoidal;
supplying a second low frequency pulsed DC power signal to an edge ring surrounding the lower electrode, wherein the second low frequency pulsed DC power signal is non-sinusoidal; and
substantially aligning the second low frequency pulsed DC power signal to a frequency and phase and pulse shape of the first low frequency pulsed DC power signal.

13. The method of claim 12, wherein the substantially aligning the second low frequency pulsed DC power signal includes:
measuring potential at a substrate to determine a first voltage signal;
measuring potential at the edge ring to determine a second voltage signal; and
tuning a voltage of the second low frequency pulsed DC power signal until a second slope of the second voltage signal substantially matches a first slope of the first voltage signal.

14. The method of claim 12, wherein the substantially aligning the second low frequency pulsed DC power signal includes:
measuring potential at a substrate to determine a first voltage signal;
measuring potential at the edge ring to determine a second voltage signal; and
tuning a voltage of the second low frequency pulsed DC power signal to match a predetermined voltage setpoint.

15. The method of claim 12, further comprising:
electrically coupling a first nanosecond DC pulsing generator to the lower electrode, wherein the coupling between the first nanosecond DC pulsing generator and the lower electrode is matchless; and
electrically coupling a second nanosecond DC pulsing generator to a coupling ring that is adjacent to the edge ring, wherein the coupling between the second nanosecond DC pulsing generator and the coupling ring is matchless.

16. The method of claim 15,
wherein the second low frequency pulsed DC power signal is delivered to the edge ring via capacitive coupling between the coupling ring and the edge ring.

17. The method of claim 15,
wherein the first nanosecond DC pulsing generator is configured as a master,
wherein the second nanosecond DC pulsing generator is configured as a slave.

18. The method of claim 12, further comprising:
supplying a high frequency radio frequency (RF) power signal to an upper electrode disposed above the lower electrode,
wherein the high frequency RF power signal is sinusoidal.

19. The method of claim 12,
wherein the first low frequency pulsed DC power signal is configured as a square pulse with a duty cycle of less than 50 percent.

20. The method of claim 19,
wherein the square pulse has a width between 200-1000 nanoseconds,
wherein the square pulse is the pulse shape.

21. The method of claim 12,
wherein the first low frequency pulsed DC power signal is configured to have a frequency between 100-800 kHz.

22. The method of claim 12,
wherein the plasma chamber is configured as a capacitively coupled plasma chamber.
